(19) United States
(12) Patent Application Publication
(10) Pub. No.: US 2024/0305247 A1
(43) Pub. Date: Sep. 12, 2024

(54) POWER AMPLIFIER CIRCUIT

(71) Applicant: Murata Manufacturing Co., Ltd., Nagaokakyo-shi (JP)

(72) Inventors: Kenji TAHARA, Nagaokakyo-shi (JP); Takeshi KOGURE, Nagaokakyo-shi (JP); Kae YAMAMOTO, Nagaokakyo-shi (JP)

(73) Assignee: Murata Manufacturing Co., Ltd., Nagaokakyo-shi (JP)

(21) Appl. No.: 18/666,857

(22) Filed: May 17, 2024

Related U.S. Application Data
(63) Continuation of application No. PCT/JP2022/041524, filed on Nov. 8, 2022.

(30) Foreign Application Priority Data
Nov. 18, 2021 (JP) 2021-187831

(51) Int. Cl. H03F 1/02; H03F 3/24

(52) U.S. Cl. CPC H03F 1/0288; H03F 3/245; H03F 2200/451

(57) ABSTRACT

A power amplifier circuit includes a carrier amplifier, a peak amplifier, an external output terminal, a combiner that includes an input terminal connected to an output terminal of the power amplifier, an input terminal connected to an output terminal of the power amplifier, and an output terminal connected to the external output terminal, a bias circuit that supplies a DC bias current to the carrier amplifier, a bias circuit that supplies a DC bias current to the peak amplifier, and a current limit circuit that is connected between the power amplifier and the bias circuit and that is configured to change a magnitude of the DC bias current according to a magnitude of a power supply voltage applied to the power amplifier circuit.

### CROSS-REFERENCE TO RELATED APPLICATIONS

This is a continuation application of PCT/JP2022/041524, filed on Nov. 8, 2022, designating the United States of America, which is based on and claims priority to Japanese Patent Application No. JP 2021-187831, filed on Nov. 18, 2021. The entire contents of the above-identified applications, including the specifications, drawings and claims, are incorporated herein by reference in their entirety.

### TECHNICAL FIELD

The present disclosure relates to a power amplifier circuit.

### BACKGROUND ART

In recent years, a tracking mode is used to dynamically adjust a power supply voltage applied to a power amplifier circuit in order to improve the efficiency of the power amplifier circuit that amplifies a radio frequency signal. For example, in an average power tracking (APT) mode, the power supply voltage is dynamically adjusted based on average power. Further, for example, in an envelope tracking (ET) mode, the power supply voltage is dynamically adjusted based on an envelope signal. Patent Document 1 discloses a system that applies a power supply voltage having a voltage level selected from among a plurality of discrete voltage levels to a power amplifier circuit in an ET mode.

Further, a Doherty amplifier may be used to improve the efficiency of the power amplifier circuit. Patent Document 2 discloses a Doherty amplifier including a carrier amplifier, a peak amplifier, and a transformer.

### CITATION LIST

### Patent Document

Patent Document 1: U.S. Pat. No. 8,829,993
Patent Document 2: Japanese Unexamined Patent Application Publication No. 2013-85179

### SUMMARY

### Technical Problem

However, when the tracking mode is applied to the power amplifier circuit including the carrier amplifier and the peak amplifier, deterioration of the characteristics of the power amplifier circuit may be caused.

Therefore, the present disclosure provides a power amplifier circuit that can suppress the deterioration of the amplification characteristics due to the tracking mode.

### Solution to Problem

A power amplifier circuit according to an aspect of the present disclosure includes: a carrier amplifier; a first peak amplifier; an external output terminal; a combiner that includes a first input terminal connected to an output terminal of the carrier amplifier, a second input terminal connected to an output terminal of the first peak amplifier, and a first output terminal connected to the external output terminal; a first bias circuit configured to supply a first DC bias current to the carrier amplifier; a second bias circuit configured to supply a second DC bias current to the first peak amplifier; and a first modulation circuit that is connected between the first peak amplifier and the second bias circuit, and configured to change a magnitude of the second DC bias current according to a magnitude of a power supply voltage applied to the power amplifier circuit.

A power amplifier circuit according to an aspect of the present disclosure includes: a carrier amplifier; a first peak amplifier; an external output terminal; a combiner that includes a first input terminal connected to an output terminal of the carrier amplifier, a second input terminal connected to an output terminal of the first peak amplifier, and a first output terminal connected to the external output terminal; a first bias circuit configured to supply a first DC bias current to the carrier amplifier; a second bias circuit configured to supply a second DC bias current to the first peak amplifier; and a first comparator circuit that is connected to the second bias circuit and configured to switch a magnitude of a first power supply voltage applied to the second bias circuit according to a magnitude of a power supply voltage applied to the power amplifier circuit.

A power amplifier circuit according to an aspect of the present disclosure includes: a carrier amplifier; a peak amplifier; an external output terminal; a transformer that includes an input side coil of which both ends are respectively connected to an output terminal of the carrier amplifier and an output terminal of the peak amplifier and an output side coil of which both ends are respectively connected to the external output terminal and a ground; a first bias circuit configured to supply a first DC bias current to the carrier amplifier; a second bias circuit configured to supply a second DC bias current to the peak amplifier; and a modulation circuit that is connected between the peak amplifier and the second bias circuit and configured to change a magnitude of the second DC bias current according to a magnitude of a power supply voltage applied to the power amplifier circuit.

### Effects

According to a power amplifier circuit of one aspect of the present disclosure, it is possible to suppress the deterioration of the amplification characteristics due to a tracking mode.

### BRIEF DESCRIPTION OF DRAWINGS

FIG. 1A is a graph showing an example of transition of a power supply voltage in a digital ET mode.

FIG. 1B is a graph showing an example of transition of a power supply voltage in an analog ET mode.

FIG. 1C is a graph showing an example of transition of a power supply voltage in an APT mode.

FIG. 2 is a circuit configuration diagram of a power amplifier circuit, a radio frequency circuit, and a communication device according to Embodiment 1.

FIG. 3 is a circuit configuration diagram of the power amplifier circuit according to Embodiment 1.

FIG. 4 is a graph showing a relationship between a DC bias current and a power supply voltage according to Embodiment 1.

FIG. 5A is a graph showing a relationship between a gain and an output power of the power amplifier circuit according to a comparative example.

FIG. 5B is a graph showing a relationship between a gain and an output power of the power amplifier circuit according to Embodiment 1.

FIG. 5C is a graph showing a relationship between a gain and an output power of the power amplifier circuit to which a power supply voltage having a voltage level V1 is applied.

FIG. 5D is a graph showing a relationship between a gain and an output power of the power amplifier circuit to which a power supply voltage having a voltage level V2 is applied.

FIG. 6 is a circuit configuration diagram of the power amplifier circuit, the radio frequency circuit, and the communication device according to Embodiment 2.

FIG. 7 is a circuit configuration diagram of the power amplifier circuit according to Embodiment 2.

FIG. 8 is a graph showing a relationship between a DC bias current and a power supply voltage according to Embodiment 2.

FIG. 9 is a graph showing a relationship between a gain and an output power of the power amplifier circuit according to Embodiment 2.

FIG. 10 is a circuit configuration diagram of the power amplifier circuit according to Modification Example 1.

FIG. 11 is a circuit configuration diagram of the power amplifier circuit according to Modification Example 2.

FIG. 12 is a graph showing a relationship between a DC bias current and a power supply voltage according to Modification Example 2.

FIG. 13 is a circuit configuration diagram of the power amplifier circuit according to Modification Example 3.

FIG. 14 is a graph showing a relationship between a DC bias current and a power supply voltage according to Modification Example 3.

FIG. 15 is a circuit configuration diagram of the power amplifier circuit according to Modification Example 4.

### DESCRIPTION OF EMBODIMENTS

Hereinafter, embodiments of the present disclosure will be described in detail with reference to the accompanying drawings. The embodiments described below are all comprehensive or specific examples. Numerical values, shapes, materials, configuration elements, the arrangement and connection form of the configuration elements, and so forth that are described in the following embodiments are merely examples and are not limiting.

Each figure is a schematic diagram with emphasis, omission, or ratio adjustment as appropriate and is not necessarily strictly shown, and the actual shape, positional relationship, and ratio may differ. In each figure, the same reference numerals are attached to substantially the same configuration, and duplicate descriptions may be omitted or simplified.

In the circuit configuration disclosed herein, “connected” includes not only a case of being directly connected by a connection terminal and/or a wiring conductor but also a case of being electrically connected with another circuit element interposed therebetween. “Connected between A and B” means connected to both A and B between A and B, and means connected in series to a path connecting A and B.

### [1 Description of Tracking Mode]

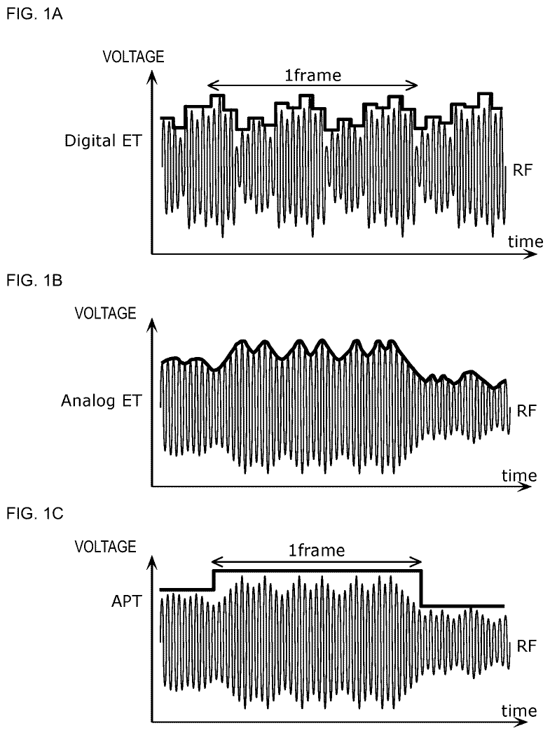

First, a tracking mode for dynamically adjusting a power supply voltage applied to a power amplifier circuit will be described. Here, as examples of the tracking mode, a digital ET mode, an analog ET mode, and an APT mode will be described with reference to FIGS. 1A to 1C.

FIG. 1A is a graph showing an example of transition of a power supply voltage in the digital ET mode. In FIG. 1A, the horizontal axis represents time, and the vertical axis represents a voltage. Further, the thick solid line represents a power supply voltage, and the thin solid line (waveform) represents a modulated signal.

In the digital ET mode, an envelope of a modulated signal is tracked by fluctuating the power supply voltage to a plurality of discrete voltage levels within one frame. As a result, the power supply voltage signal forms a rectangular wave. In the digital ET mode, a power supply voltage level is selected or set from among the plurality of discrete voltage levels based on an envelope signal.

The frame corresponds to a unit configuring a radio frequency signal (a modulated signal). For example, in 5th generation new radio (5GNR) and long term evolution (LTE), a frame includes 10 subframes, each subframe includes a plurality of slots, and each slot is configured with a plurality of symbols. A subframe length is 1 ms, and a frame length is 10 ms.

The envelope signal is a signal indicating an envelope of a modulated signal. An envelope value is represented, for example, with the square root of (I²+Q²). Here, (I, Q) represents a constellation point. The constellation point is a point on a constellation diagram that represents a signal modulated by digital modulation. (I, Q) is determined with the BBIC 4, for example, based on the transmission information.

FIG. 1B is a graph showing an example of transition of a power supply voltage in the analog ET mode. In FIG. 1B, the horizontal axis represents time, and the vertical axis represents a voltage. Further, the thick solid line represents a power supply voltage, and the thin solid line (waveform) represents a modulated signal.

In the analog ET mode, an envelope of a modulated signal is tracked by continuously fluctuating the power supply voltage. In the analog ET mode, the power supply voltage is determined based on the envelope signal. In the analog ET mode, when the envelope of the modulated signal is changed at high speed, it is difficult for the power supply voltage to track the envelope.

FIG. 1C is a graph showing an example of transition of a power supply voltage in the APT mode. In FIG. 1C, the horizontal axis represents time, and the vertical axis represents a voltage. Further, the thick solid line represents a power supply voltage, and the thin solid line (waveform) represents a modulated signal.

In the APT mode, the power supply voltage fluctuates to a plurality of discrete voltage levels in one frame unit. As a result, the power supply voltage signal forms a rectangular wave. In the APT mode, the voltage level of the power supply voltage is determined based on an average output power rather than the envelope signal. In the APT mode, the voltage level may be changed in a unit (for example, subframe) smaller than one frame.

By applying the tracking mode as described above to the power amplifier circuit, the improvement of the amplification efficiency of the power amplifier circuit is achieved. However, such a tracking mode may cause deterioration of the characteristics of the power amplifier circuit.

For example, when the digital ET mode is applied to the power amplifier circuit, the gain of the power amplifier circuit may be changed abruptly when the voltage level of the power supply voltage is changed. An abrupt change in gain has a frequency component, and this may cause cross-modulation and/or intermodulation distortion.

Therefore, a power amplifier circuit including a carrier amplifier and a peak amplifier that can suppress deterioration of the characteristics due to the tracking mode will be described based on embodiments.

### Embodiment 1

### [2.1 Circuit Configuration of Communication Device 6A, Radio Frequency Circuit 1A, and Power Amplifier Circuit 10A]

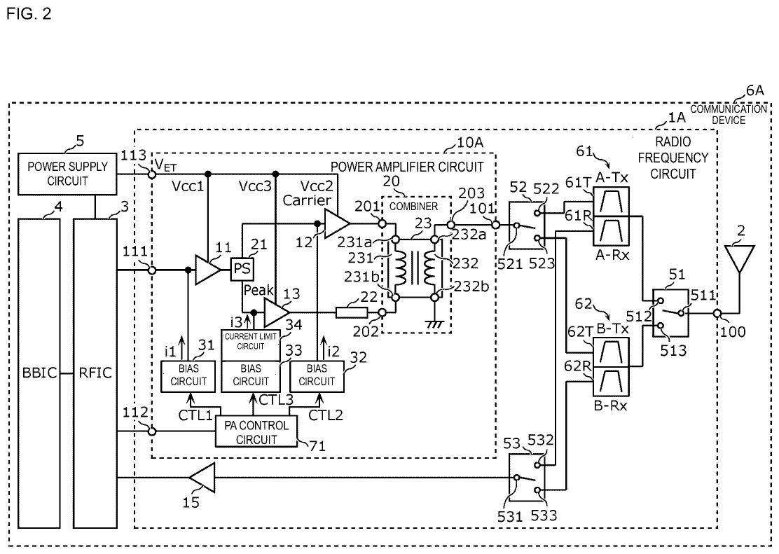

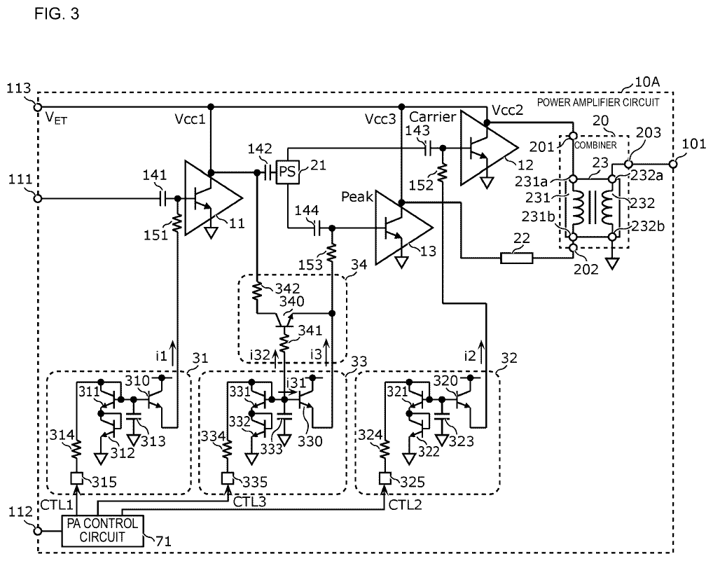

Circuit configurations of a communication device 6A, a radio frequency circuit 1A, and a power amplifier circuit 10A according to Embodiment 1 will be described with reference to FIGS. 2 and 3. FIG. 2 is a circuit configuration diagram of the power amplifier circuit 10A, the radio frequency circuit 1A, and the communication device 6A according to the present embodiment. FIG. 3 is a circuit configuration diagram of the power amplifier circuit 10A according to the present embodiment.

### [2.1.1 Circuit Configuration of Communication Device 6A]

First, the circuit configuration of the communication device 6A will be described. As shown in FIG. 2, the communication device 6A according to the present embodiment includes the radio frequency circuit 1A, an antenna 2, a radio frequency integrated circuit (RFIC) 3, a baseband integrated circuit (BBIC) 4, and a power supply circuit 5.

The radio frequency circuit 1A transmits a radio frequency signal between the antenna 2 and the RFIC 3. The internal configuration of the radio frequency circuit 1A will be described later.

The antenna 2 is connected to an antenna connection terminal 100 of the radio frequency circuit 1A and transmits the radio frequency signal that is output from the radio frequency circuit 1A.

The RFIC 3 is an example of a signal processing circuit that processes the radio frequency signal. Specifically, the RFIC 3 performs signal processing, such as downconversion, on a radio frequency reception signal, which is input through a receive path of the radio frequency circuit 1A, and outputs the received signal generated through the signal processing to the BBIC 4. Further, the RFIC 3 performs the signal processing, such as upconversion, on the transmission signal, which is input from the BBIC 4, and outputs a radio frequency transmission signal generated through the signal processing to a transmit path of the radio frequency circuit 1A. Further, the RFIC 3 includes a control unit that controls the radio frequency circuit 1A and the power supply circuit 5. A part or all of the functions of the RFIC 3 as the control unit may be mounted outside the RFIC 3 or may be mounted in the BBIC 4 or the radio frequency circuit 1A, for example.

The BBIC 4 is a baseband signal processing circuit that performs the signal processing using an intermediate frequency band lower in frequency than the radio frequency signal transmitted by the radio frequency circuit 1A. As a signal processed by the BBIC 4, for example, an image signal for image display and/or an audio signal for a call through a speaker are used.

The power supply circuit 5 can apply the power supply voltage to the power amplifier circuit 10A. In the present embodiment, the power supply circuit 5 is a digital envelope tracker that can apply the power supply voltage having a plurality of discrete voltage levels. Specifically, the power supply circuit 5 can apply the power supply voltage having a plurality of discrete voltage levels that tracks an envelope of the radio frequency signal according to a control signal from the RFIC 3. For example, the power supply circuit 5 prepares the power supply voltage having a plurality of discrete voltage levels in advance and uses a switch (not shown) to select and output one voltage level from among the plurality of voltage levels prepared in advance. Accordingly, the power supply circuit 5 can switch the voltage level of the power supply voltage to be applied to the power amplifier circuit 10A at high speed by using the switch. The power supply circuit 5 does not necessarily prepare a plurality of voltage levels in advance or does not necessarily select and output a voltage level by using the switch. For example, the power supply circuit 5 may generate and output a voltage level selected from among the plurality of discrete voltage levels at any time.

The power supply circuit 5 is not limited to a digital envelope tracker that can apply the power supply voltage to the power amplifier circuit 10A in the digital ET mode. For example, the power supply circuit 5 may be an analog envelope tracker that can apply the power supply voltage to the power amplifier circuit 10A in the analog ET mode and may be an average power tracker that can apply the power supply voltage to the power amplifier circuit 10A in the APT mode. Furthermore, the power supply circuit 5 may be any combination of a digital envelope tracker, an analog envelope tracker, and an average power tracker.

The circuit configuration of the communication device 6A represented in FIG. 2 is an example, and the circuit configuration is not limited thereto. For example, the communication device 6A does not necessarily include the antenna 2 and/or the BBIC 4. Further, for example, the communication device 6A may include a plurality of antennas.

### [2.1.2 Circuit Configuration of Radio Frequency Circuit 1A]

Next, a circuit configuration of the radio frequency circuit 1A will be described. As shown in FIG. 2, the radio frequency circuit 1A includes the power amplifier circuit 10A, a low-noise amplifier 15, switches 51 to 53, duplexers 61 and 62, and an antenna connection terminal 100. Hereinafter, the configuration elements of the radio frequency circuit 1A will be described in order.

The antenna connection terminal 100 is connected to the switch 51 in the radio frequency circuit 1A and connected to the antenna 2 outside the radio frequency circuit 1A. The transmission signals in the bands A and B, which are amplified by the power amplifier circuit 10A, are output to the antenna 2 through the antenna connection terminal 100. Further, the reception signals in the bands A and B, which are received by the antenna 2, are input to the radio frequency circuit 1A through the antenna connection terminal 100.

The power amplifier circuit 10A is a Doherty amplifier and can amplify the transmission signals in the bands A and B. The internal configuration of the power amplifier circuit 10A will be described later.

The switch 51 is connected between the antenna connection terminal 100 and the duplexers 61 and 62. The switch 51 includes terminals 511 to 513. The terminal 511 is connected to the antenna connection terminal 100. The terminal 512 is connected to the duplexer 61. The terminal 513 is connected to the duplexer 62.

In the connection configuration, the switch 51 can connect the terminal 511 to any of the terminals 512 and 513, for example, based on the control signal from the RFIC 3. That is, the switch 51 can switch the connection of the antenna connection terminal 100 between the duplexers 61 and 62. The switch 51 is configured with, for example, a single-pole double-throw (SPDT) type switch circuit.

The switch 52 is connected between transmission filters 61T and 62T and the power amplifier circuit 10A. The switch 52 includes terminals 521 to 523. The terminal 521 is connected to the power amplifier circuit 10A. The terminal 522 is connected to the transmission filter 61T. The terminal 523 is connected to the transmission filter 62T.

In the connection configuration, the switch 52 can connect the terminal 521 to any of the terminals 522 and 523, for example, based on the control signal from the RFIC 3. That is, the switch 52 can switch the connection of the power amplifier circuit 10A between the transmission filters 61T and 62T. The switch 52 is configured with, for example, an SPDT type switch circuit.

The switch 53 is connected between reception filters 61R and 62R and the low-noise amplifier 15. The switch 53 includes terminals 531 to 533. The terminal 531 is connected to the low-noise amplifier 15. The terminal 532 is connected to the reception filter 61R. The terminal 533 is connected to the reception filter 62R.

In the connection configuration, the switch 53 can connect the terminal 531 to either of the terminals 532 and 533, for example, based on the control signal from the RFIC 3. That is, the switch 53 can switch the connection of the low-noise amplifier 15 between the reception filters 61R and 62R. The switch 53 is configured with, for example, an SPDT type switch circuit.

The duplexer 61 includes a passband that includes the band A. The duplexer 61 includes the transmission filter 61T and the reception filter 61R, and enables frequency division duplex (FDD) in the band A.

The transmission filter 61T (A-Tx) is connected between the power amplifier circuit 10A and the antenna connection terminal 100. Specifically, one end of the transmission filter 61T is connected to the power amplifier circuit 10A with the switch 52 interposed therebetween. On the other hand, the other end of the transmission filter 61T is connected to the antenna connection terminal 100 with the switch 51 interposed therebetween. The transmission filter 61T includes a passband that includes an uplink operating band of the band A. Accordingly, the transmission filter 61T can pass the transmission signal in the band A among the transmission signals amplified by the power amplifier circuit 10A.

The reception filter 61R (A-Rx) is connected between the low-noise amplifier 15 and the antenna connection terminal 100. Specifically, one end of the reception filter 61R is connected to the antenna connection terminal 100 with the switch 51 interposed therebetween. On the other hand, the other end of the reception filter 61R is connected to the low-noise amplifier 15 with the switch 53 interposed therebetween. The reception filter 61R includes a passband that includes a downlink operating band of the band A. Accordingly, the reception filter 61R can pass the reception signal in the band A among the reception signals received by the antenna 2.

The duplexer 62 includes a passband that includes the band B. The duplexer 62 includes the transmission filter 62T and the reception filter 62R, and enables FDD in the band B.

The transmission filter 62T (B-Tx) is connected between the power amplifier circuit 10A and the antenna connection terminal 100. Specifically, one end of the transmission filter 62T is connected to the power amplifier circuit 10A with the switch 52 interposed therebetween. On the other hand, the other end of the transmission filter 62T is connected to the antenna connection terminal 100 with the switch 51 interposed therebetween. The transmission filter 62T includes a passband that includes an uplink operating band of the band B. Accordingly, the transmission filter 62T can pass the transmission signal in the band B among the transmission signals amplified by the power amplifier circuit 10A.

The reception filter 62R (B-Rx) is connected between the low-noise amplifier 15 and the antenna connection terminal 100. Specifically, one end of the reception filter 62R is connected to the antenna connection terminal 100 with the switch 51 interposed therebetween. On the other hand, the other end of the reception filter 62R is connected to the low-noise amplifier 15 with the switch 53 interposed therebetween. The reception filter 62R includes a passband that includes a downlink operating band of the band B. Accordingly, the reception filter 62R can pass the reception signal in the band B among the reception signals received by the antenna 2.

The bands A and B are frequency bands for a communication system built using radio access technology (RAT). The bands A and B are defined in advance with the standardizing body and the like (for example, 3rd generation partnership project (3GPP (registered trademark)), the institute of electrical and electronics engineers (IEEE), and the like). Examples of the communication system include a 5GNR system, an LTE system, a wireless local area network (WLAN) system, and the like.

The radio frequency circuit 1A represented in FIG. 2 is an example, and the present disclosure is not limited thereto. For example, the radio frequency circuit 1A does not necessarily include the duplexer 62 or does not necessarily include the switches 51 to 53. Further, the radio frequency circuit 1A does not necessarily include the receive path or does not necessarily include the low-noise amplifier 15 and the reception filter 61R. Further, for example, the radio frequency circuit 1A may include a filter and a power amplifier circuit corresponding to a band C different from the bands A and B.

### [2.1.3 Circuit Configuration of Power Amplifier Circuit 10A]

Next, the circuit configuration of the power amplifier circuit 10A will be described. As shown in FIGS. 2 and 3, the power amplifier circuit 10A includes power amplifiers 11 to 13, a combiner 20, a phase shifter (PS) 21, a transmission line 22, bias circuits 31 to 33, a current limit circuit 34, a power amplifier (PA) control circuit 71, an external output terminal 101, an external input terminal 111, a control terminal 112, a power supply terminal 113, capacitors 141 to 144, and resistance elements 151 to 153. Hereinafter, the configuration elements of the power amplifier circuit 10A will be described in order.

The external input terminal 111 is a terminal for receiving the transmission signals in the bands A and B from the outside of the power amplifier circuit 10A. The external input terminal 111 is connected to the RFIC 3 outside the power amplifier circuit 10A and connected to the power amplifier 11 inside the power amplifier circuit 10A. Accordingly, the transmission signals in the bands A and B, which are received from the RFIC 3 through the external input terminal 111, are supplied to the power amplifier 11.

The control terminal 112 is a terminal for transmitting the control signal. That is, the control terminal 112 is a terminal for receiving the control signal from the outside of the power amplifier circuit 10A and/or a terminal for supplying the control signal to the outside of the power amplifier circuit 10A.

The power supply terminal 113 is a terminal for receiving the power supply voltage V_{ET} from the power supply circuit 5. The power supply terminal 113 is connected to the power supply circuit 5 outside the power amplifier circuit 10A and connected to the power amplifiers 11 to 13 inside the power amplifier circuit 10A. Accordingly, the power supply voltage V_{ET}, which is received from the power supply circuit 5 through the power supply terminal 113, is applied to each of the power amplifiers 11 to 13 as Vcc1, Vcc2, and Vcc3.

The power amplifier 11 is connected between the external input terminal 111 and the power amplifiers 12 and 13. Specifically, an input terminal of the power amplifier 11 is connected to the external input terminal 111. An output terminal of the power amplifier 11 is connected to the power amplifiers 12 and 13 with the phase shifter 21 interposed therebetween. In the present embodiment, although the power amplifier 11 includes a bipolar transistor as an amplifier transistor, the power amplifier 11 may include a metal-oxide-semiconductor field-effect-transistor (MOSFET) instead of a bipolar transistor.

In the connection configuration, the power amplifier 11 can amplify the transmission signals in the bands A and B, which are received through the external input terminal 111, by using a DC bias current i1, which is supplied from the bias circuit 31, and the power supply voltage Vcc1 received through the power supply terminal 113. The power amplifier 11 configures an input stage (a drive stage) of multistage amplifier circuit.

The phase shifter 21 is connected between the power amplifier 11 and the power amplifiers 12 and 13. Specifically, an input terminal of the phase shifter 21 is connected to the power amplifier 11, and two output terminals of the phase shifter 21 are respectively connected to the power amplifiers 12 and 13.

In the connection configuration, the phase shifter 21 can distribute signals amplified by the power amplifier 11 and output the signals to the power amplifiers 12 and 13. At this time, the phase shifter 21 can adjust phases of the two distributed signals. For example, the phase shifter 21 can shift the signal, which is output to the power amplifier 12, by −90 degrees (delay by 90 degrees) with respect to the signal, which is output to the power amplifier 13. The adjustment of the phase in the phase shifter 21 is not limited to the above. For example, a phase difference between the two distributed signals may be appropriately changed according to the internal configuration of the power amplifier circuit 10A.

The power amplifier 12 is an example of a carrier amplifier and is connected between the external input terminal 111 and the external output terminal 101. Specifically, an input terminal of the power amplifier 12 is connected to an output terminal of the power amplifier 11 with the phase shifter 21 interposed therebetween. The output terminal of the power amplifier 12 is connected to the input terminal 201 of the combiner 20. In the present embodiment, although the power amplifier 12 includes a bipolar transistor as an amplifier transistor, the power amplifier 12 may include a MOSFET instead of the bipolar transistor.

In the connection configuration, the power amplifier 12 can amplify the transmission signals in the bands A and B, which are amplified by the power amplifier 11, by using a DC bias current i2, which is supplied from the bias circuit 32, and the power supply voltage Vcc2 received through the power supply terminal 113. For example, a class AB amplifier is used as the power amplifier 12, and the power amplifier 12 configures an output stage (power stage) of a multistage amplifier circuit together with the power amplifier 13. The power amplifier 12 is not limited to the class AB amplifier. For example, a class A amplifier may be used as the power amplifier 12.

The power amplifier 13 is an example of a first peak amplifier and is connected between the external input terminal 111 and the external output terminal 101. Specifically, an input terminal of the power amplifier 13 is connected to an output terminal of the power amplifier 11 with the phase shifter 21 interposed therebetween. The output terminal of the power amplifier 13 is connected to the input terminal 202 of the combiner 20 with the transmission line 22 interposed therebetween. In the present embodiment, although the power amplifier 13 includes a bipolar transistor as an amplifier transistor, the power amplifier 13 may include a MOSFET instead of the bipolar transistor.

In the connection configuration, the power amplifier 13 can amplify the transmission signals in the bands A and B, which are amplified by the power amplifier 11, by using a DC bias current i3, which is supplied from the bias circuit 33 through the current limit circuit 34, and the power supply voltage Vcc3 received through the power supply terminal 113. For example, a class C amplifier is used as the power amplifier 13, and the power amplifier 13 configures an output stage (power stage) of a multistage amplifier circuit together with the power amplifier 12. The power amplifier 13 is not limited to the class C amplifier. For example, a class AB amplifier may be used as the power amplifier 13.

The Doherty amplifier corresponds to an amplifier that achieves high efficiency by using a plurality of amplifiers as carrier amplifiers and peak amplifiers. The carrier amplifier corresponds to an amplifier that operates regardless of whether the power of the radio frequency signal (input) is low or high in the Doherty amplifier. The peak amplifier corresponds to an amplifier that mainly operates when the power of the radio frequency signal (input) is high in the Doherty amplifier. Therefore, the radio frequency signal is mainly amplified by the carrier amplifier when the input power of the radio frequency signal is low, and the radio frequency signal is amplified and combined by the carrier amplifier and the peak amplifier when the input power of the radio frequency signal is high. Due to such an operation, in the Doherty amplifier, a load impedance that is seen from the carrier amplifier is increased at low output power, and amplification efficiency at low output power is improved.

The transmission line 22 is, for example, a ¼ wavelength transmission line and can rotate a load impedance by 180 degrees on the Smith chart. The transmission line 22 may be referred to as a phase adjuster or a phase shifter. A length of the transmission line 22 is determined based on the bands A and B. The transmission line 22 is connected between the output terminal of the power amplifier 13 and the input terminal 202 of the combiner 20. In the connection configuration, the transmission line 22 can shift the phase of the transmission signal in the bands A and B, which are amplified by the power amplifier 13, by −90 degrees (delay by 90 degrees). The transmission line 22 may include at least one of an inductor and a capacitor. Accordingly, the reduction in length of the transmission line 22 can be achieved.

The combiner 20 includes the input terminals 201 and 202 and an output terminal 203. The input terminal 201 is an example of a first input terminal and is connected to the output terminal of the power amplifier 12. The input terminal 202 is an example of a second input terminal and is connected to the output terminal of the power amplifier 13 with the transmission line 22 interposed therebetween. The output terminal 203 is an example of a first output terminal and is connected to the external output terminal 101.

In the present embodiment, the combiner 20 includes a transformer 23. The transformer 23 includes an input side coil 231 and an output side coil 232. Both ends 231a and 231b of the input side coil 231 are respectively connected to the input terminals 201 and 202. Specifically, one end 231a of the input side coil 231 is connected to the output terminal of the power amplifier 12 with the input terminal 201 interposed therebetween, and the other end 231b of the input side coil 231 is connected to the output terminal of the power amplifier 13 with the input terminal 202 and the transmission line 22 interposed therebetween. Both ends 232a and 232b of the output side coil 232 are respectively connected to the output terminal 203 and the ground. Specifically, one end 232a of the output side coil 232 is connected to the external output terminal 101, and the other end 232b of the output side coil 232 is connected to the ground.

In the configuration, the combiner 20 can combine two input signals, which are from the input terminals 201 and 202, and output the input signals from the output terminal 203. Further, the combiner 20 can also output the input signal, which is from the input terminal 201, from the output terminal 203.

The external output terminal 101 is a terminal for supplying the transmission signals in the bands A and B, which are amplified by the power amplifier circuit 10A, to the outside of the power amplifier circuit 10A. The external output terminal 101 is connected to the combiner 20 inside the power amplifier circuit 10A and connected to the switch 52 outside the power amplifier circuit 10A. Accordingly, the transmission signal, which is supplied through the external output terminal 101, is transmitted to the antenna connection terminal 100 through the transmission filters 61T and 62T.

As shown in FIG. 3, the bias circuit 31 includes a constant current amplifier transistor 310, diode-connected transistors 311 and 312, a capacitor 313, a resistance element 314, and a constant current source 315. In the configuration, the bias circuit 31 can supply the DC bias current i1 to a base terminal of the power amplifier 11.

Specifically, a constant current, which is output from the constant current source 315, is input to a base terminal of the constant current amplifier transistor 310. The constant current, which is input to the base terminal of the constant current amplifier transistor 310, is amplified to the DC bias current i1 by the constant current amplifier transistor 310. The DC bias current i1 is applied from an emitter terminal of the constant current amplifier transistor 310 to the base terminal of the power amplifier 11 through the resistance element 151. The constant current source 315 can switch whether or not to generate the constant current based on a control signal CTL1 from a PA control circuit 71.

The bias circuit 32 Is an example of a first bias circuit, and as shown in FIG. 3, includes a constant current amplifier transistor 320, diode-connected transistors 321 and 322, a capacitor 323, a resistance element 324, and a constant current source 325. In the configuration, the bias circuit 32 can supply the DC bias current i2 (the first DC bias current) to a base terminal of the power amplifier 12.

Specifically, a constant current, which is output from the constant current source 325, is input to a base terminal of the constant current amplifier transistor 320. The constant current, which is input to the base terminal of the constant current amplifier transistor 320, is amplified to the DC bias current i2 by the constant current amplifier transistor 320. The DC bias current i2 is applied from an emitter terminal of the constant current amplifier transistor 320 to the base terminal of the power amplifier 12 through the resistance element 152. The constant current source 325 can switch whether or not to generate the constant current based on a control signal CTL2 from the PA control circuit 71.

The bias circuit 33 is an example of a second bias circuit, and as shown in FIG. 3, includes a constant current amplifier transistor 330, diode-connected transistors 331 and 332, a capacitor 333, a resistance element 334, and a constant current source 335. In the configuration, the bias circuit 33 can output the DC bias current i3 (the second DC bias current) toward a base terminal of the power amplifier 13.

Specifically, a direct current i31, which is at least a part of the constant current output from the constant current source 335, is input to a base terminal of the constant current amplifier transistor 330. The direct current i31, which is input to the base terminal of the constant current amplifier transistor 330, is amplified to the DC bias current i3 by the constant current amplifier transistor 330. The DC bias current i3 is applied from an emitter terminal of the constant current amplifier transistor 330 to the base terminal of the power amplifier 13 through the resistance element 153. The constant current source 335 can switch whether or not to generate the constant current based on a control signal CTL3 from the PA control circuit 71.

The current limit circuit 34 is an example of a first modulation circuit, and as shown in FIG. 3, includes a current limit transistor 340 and resistance elements 341 and 342. A collector terminal of the current limit transistor 340 is connected to the power supply terminal 113 with the resistance element 342 interposed therebetween. An emitter terminal of the current limit transistor 340 is connected to the emitter terminal of the constant current amplifier transistor 330. A base terminal of the current limit transistor 340 is connected to the base terminal of the constant current amplifier transistor 330 with the resistance element 341 interposed therebetween.

With the configuration, the current limit circuit 34 can change (modulate) a magnitude of the DC bias current i3 according to the magnitude of the power supply voltage V_{ET}. Specifically, when the power supply voltage Vcc1, which is applied to the emitter terminal of the current limit transistor 340, is lower than a standard voltage Vth1 (an example of a first standard voltage), which is applied to the base terminal of the current limit transistor 340, as a potential difference between the power supply voltage Vcc1 and the standard voltage Vth1 is increased, a direct current i32 is increased, which flows from the constant current source 335 to the collector terminal of the current limit transistor 340 through the base terminal of the current limit transistor 340. As a result, the direct current i31, which is input to the base terminal of the constant current amplifier transistor 330, is decreased, and the DC bias current i3 is decreased. That is, as the power supply voltage Vcc1 is decreased, the DC bias current i3 is decreased. Conversely, as the power supply voltage Vcc1 is increased, the DC bias current i3 is increased.

As a voltage level of the standard voltage Vth1, for example, a voltage level higher than the maximum level of power supply voltage V_{ET} can be used. Accordingly, even when the power supply voltage V_{ET} fluctuates, the power supply voltage Vcc1 can always be maintained to be a state lower than the standard voltage Vth1, and the increase in DC bias current i3 can be maintained up to the maximum level of the power supply voltage V_{ET}.

The PA control circuit 71 controls the bias circuits 31 to 33. Specifically, the PA control circuit 71 respectively outputs the control signals CTL1 to CTL3 to the bias circuits 31 to 33 based on the control signal from the RFIC 3. The PA control circuit 71 may control other circuit elements (for example, the switches 51 to 53). Further, the PA control circuit 71 is not necessarily included in the power amplifier circuit 10A.

The capacitors 141 to 144 are DC cut capacitance elements that remove a DC component of the radio frequency signal.

In the power amplifier circuit 10A according to the present embodiment, the capacitors 141 to 144 and the resistance elements 151 to 153 may be deleted or replaced with other circuit elements according to the required specifications of the power amplifier circuit 10A, and are not essential configuration elements.

The circuit configuration of the power amplifier circuit 10A represented in FIGS. 2 and 3 is an example, and the present disclosure is not limited thereto. For example, the power amplifier circuit 10A does not necessarily include at least one of the power amplifier 11, the phase shifter 21, and the transmission line 22. Further, the circuit configurations of the bias circuits 31 to 33 and the current limit circuit 34 are not limited to that in FIG. 3.

### [2.2 Relationship Between DC Bias Current and Power Supply Voltage]

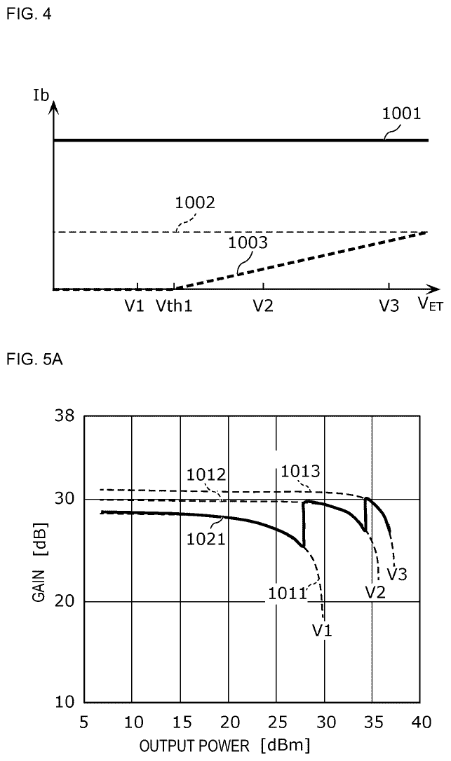

A relationship between a DC bias current Ib and the power supply voltage V_{ET}, which are respectively supplied to the power amplifiers 12 and 13 in such a power amplifier circuit 10A, will be described with reference to FIG. 4.

FIG. 4 is a graph showing a relationship between the DC bias current Ib and the power supply voltage V_{ET} in the present embodiment. In FIG. 4, the vertical axis indicates the DC bias current Ib, and the horizontal axis indicates the power supply voltage V_{ET}.

A line 1001 indicates a DC bias current supplied to the power amplifier 12 (the carrier amplifier). A line 1002 indicates a DC bias current supplied to the peak amplifier according to a comparative example. A line 1003 indicates a DC bias current supplied to the power amplifier 13 (the peak amplifier).

In the comparative example, a constant current that does not depend on the magnitude of the power supply voltage V_{ET} and that is smaller than that of the carrier amplifier is supplied to the peak amplifier (the line 1002). As described above, in a case where the DC bias current is supplied to the peak amplifier even when the power supply voltage V_{ET} is low, it is difficult to stop the operation of the peak amplifier even when the input signal level is low, thereby the increase in load impedance that is seen from the carrier amplifier is limited.

On the other hand, in the present embodiment, when the power supply voltage V_{ET} is lower than the standard voltage Vth1, the DC bias current is not supplied to the peak amplifier, and when the power supply voltage V_{ET} is higher than the standard voltage Vth1, the DC bias current, which is supplied to the peak amplifier, is increased as the power supply voltage V_{ET} is increased.

For example, in a case where V1<Vth1<V2<V3 is satisfied as in FIG. 4, when the power supply voltage V_{ET} having the voltage level V1 is applied to the peak amplifier, the DC bias current is not supplied to the peak amplifier. Further, when the power supply voltage V_{ET} having the voltage level V3 is applied to the peak amplifier, the DC bias current, which is supplied to the peak amplifier, is larger than the DC bias current, which is supplied to the peak amplifier when the power supply voltage V_{ET} having the voltage level V2 is applied to the peak amplifier.

As described above, by the fact that the lower the voltage level of the power supply voltage V_{ET}, the more the DC bias current is limited, the peak amplifier operation can be further suppressed when the input signal level is low, and it is possible to increase the load impedance that is seen from the carrier amplifier. As a result, the carrier amplifier can be operated with high efficiency, and the gain of the carrier amplifier can be increased.

### [2.3 Change in Gain in Digital ET Mode]

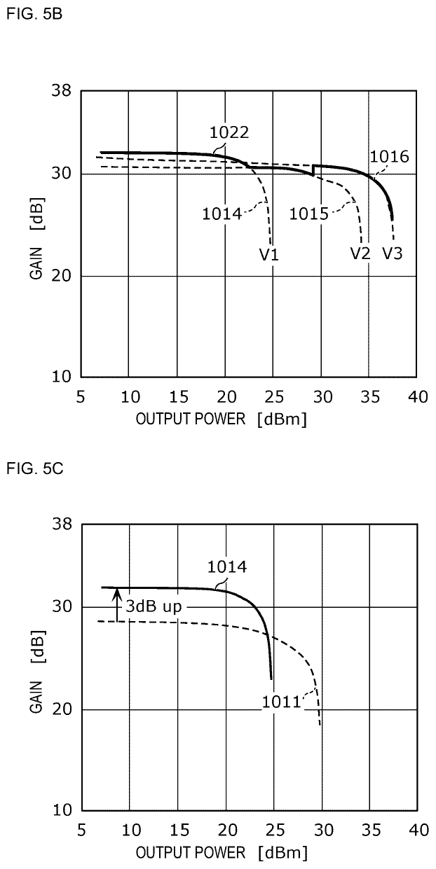

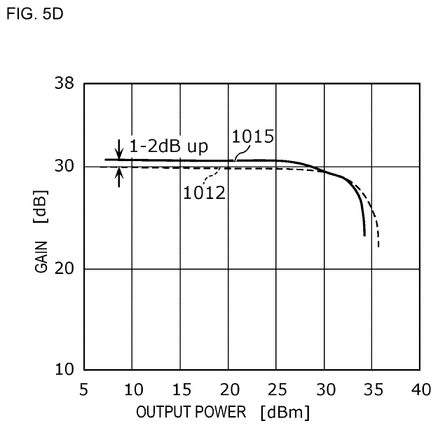

Here, a relationship between the gain and output power of the power amplifier circuit 10A in the digital ET mode in which three discrete voltage levels V1 to V3 are selectively applied based on the envelope signal will be described with reference to FIGS. 5A and 5B. Hereinafter, as specific examples of V1 to V3, 2.4 volts, 4.0 volts, and 5.6 volts are respectively used.

FIG. 5A is a graph showing a relationship between the gain and the output power of the power amplifier circuit according to the comparative example. FIG. 5B is a graph showing a relationship between the gain and the output power of the power amplifier circuit 10A according to the present embodiment. In FIGS. 5A and 5B, the vertical axis indicates a gain, and the horizontal axis indicates an output power.

In FIG. 5A, lines 1011 to 1013 represent the gain of the power amplifier circuit according to the comparative example when the voltage levels of the power supply voltage V_{ET} are respectively fixed to V1 to V3. Further, a line 1021 represents the gain of the power amplifier circuit according to the comparative example in the digital ET mode.

In FIG. 5B, lines 1014 to 1016 represent the gain of the power amplifier circuit 10A according to the present embodiment when the voltage levels of the power supply voltage V_{ET} are respectively fixed to V1 to V3, and a line 1022 represents the gain of the power amplifier circuit 10A according to the present embodiment in the digital ET mode.

In general, when the DC bias current is constant, as the power supply voltage is increased, the gain of the power amplifier circuit is increased in an active region, and the gain of the power amplifier circuit is decreased as the output power is increased in a saturation region.

Therefore, in the comparative example, the gain in a region (an active region) where the output power of the line 1011 is small is smaller than the gain in a region (an active region) where the output power of the line 1012 is small. Further, in a region (a saturation region) where the output power of line 1011 is large, the gain is decreased as the output power is increased.

As a result, in the comparative example, the gain is changed abruptly at the switching between the voltage levels V1 and V2 of the power supply voltage V_{ET} (the line 1021 in FIG. 5A). For example, when the voltage level of the power supply voltage V_{ET} is switched from V1 to V2 at the output power of substantially 28 dBm, the gain is increased abruptly from substantially 26 dB to substantially 30 dB. As described above, when the DC bias current of the peak amplifier is constant, the gain is abruptly changed by switching the voltage level of the power supply voltage V_{ET}.

On the other hand, in the present embodiment, the gain transitions smoothly at the switching between the voltage levels of V1 and V2 of the power supply voltage V_{ET} (the line 1022 in FIG. 5B). For example, even when the voltage level of the power supply voltage V_{ET} is switched from V1 to V2 at the output power of substantially 23 dBm, the gain transitions smoothly at substantially 30 dB.

Here, the reason why the gain fluctuation is suppressed in the present embodiment will be described with reference to FIGS. 5C and 5D. FIG. 5C is a graph showing a relationship between the gain and the output power of the power amplifier circuit to which the power supply voltage having the voltage level V1 is applied. FIG. 5D is a graph showing a relationship between the gain and the output power of the power amplifier circuit to which the power supply voltage having the voltage level V2 is applied. In FIGS. 5C and 5D, the vertical axis indicates a gain, and the horizontal axis indicates an output power. Further, the solid line represents the present embodiment, and the broken line represents the comparative example.

At the voltage level V1, although the DC bias current is not supplied to the peak amplifier in the present embodiment, the DC bias current is supplied to the peak amplifier in the comparative example. That is, although the current does not flow between the collector and emitter of the peak amplifier in the present embodiment, at least a leakage current flows between the collector and emitter of the peak amplifier in the comparative example. Therefore, the load impedance, which is viewed from the carrier amplifier in the present embodiment, is higher than that of the comparative example.

Accordingly, as shown in FIG. 5C, the gain in the present embodiment is improved by substantially 3 dB from the gain in the comparative example at the voltage level V1. As a result, the decrease in gain at the voltage level V1 with respect to the voltage level V2 is complemented. That is, an abrupt change in gain is suppressed at the switching between the voltage levels of V1 and V2 of the power supply voltage V_{ET}.

Similarly, at the voltage level V2, the DC bias current, which is supplied to the peak amplifier, is reduced in the present embodiment than that in the comparative example. That is, in the present embodiment, the current between the collector and emitter of the peak amplifier is reduced more than that of the comparative example. Therefore, the load impedance, which is viewed from the carrier amplifier in the present embodiment, is higher than that of the comparative example.

Accordingly, as shown in FIG. 5D, the gain in the present embodiment is improved by substantially 1 to 2 dB from the gain in the comparative example at the voltage level V2. As a result, the decrease in gain at the voltage level V2 with respect to the voltage level V3 is complemented. That is, an abrupt change in gain is suppressed at the switching between the voltage levels of V2 and V3 of the power supply voltage V_{ET}.

The improvement in gain by suppressing the operation of the peak amplifier is more effective when the size of the peak amplifier is larger than the size of the carrier amplifier. Therefore, the size of the peak amplifier is preferably equal to or larger than the size of the carrier amplifier, and further preferably, the size of the peak amplifier is larger than the size of the carrier amplifier.

The size of each of the carrier amplifier and the peak amplifier can be specified by measuring the size of the amplifier transistor included therein. Specifically, in plan view of an integrated circuit including the amplifier transistor, by measuring an area of a region where the amplifier transistor is formed, the size of each of the carrier amplifier and the peak amplifier can be specified.

### [2.4 Effects and the Like]

As described above, the power amplifier circuit 10A according to the present embodiment includes the power amplifier 12 (the carrier amplifier), the power amplifier 13 (the peak amplifier), the external output terminal 101, the combiner 20 that includes the input terminal 201 connected to the output terminal of the power amplifier 12, the input terminal 202 connected to the output terminal of the power amplifier 13, and the output terminal 203 connected to the external output terminal 101, the bias circuit 32 that supplies the DC bias current i2 to the power amplifier 12, the bias circuit 33 that supplies the DC bias current i3 to the power amplifier 13, and the current limit circuit 34 that is connected between the power amplifier 13 and the bias circuit 33 and that changes the magnitude of the DC bias current i3 according to the magnitude of the power supply voltage V_{ET} applied to the power amplifier circuit 10A.

According to the above, by changing the magnitude of the DC bias current i3 according to the magnitude of the power supply voltage V_{ET}, the operation of the power amplifier 13 can be controlled, and the load impedance, which is viewed from the power amplifier 12, can be controlled. That is, the gain of the power amplifier 12 can be controlled, and an abrupt change in gain of the power amplifier circuit 10A with respect to the change in power supply voltage V_{ET} Can be suppressed. As a result, it is possible to suppress the generation of noise accompanying an abrupt change in gain of the power amplifier circuit 10A, and it is possible to suppress the deterioration of the characteristics of the power amplifier circuit 10A due to the tracking mode.

Further, for example, in the power amplifier circuit 10A according to the present embodiment, the combiner 20 may include the transformer 23 including the input side coil 231 of which both ends 231a and 231b are respectively connected to the input terminals 201 and 202, and the output side coil 232 of which both ends 232a and 232b are respectively connected to the output terminal 203 and the ground.

According to the above, the voltage of the radio frequency signal can be combined by using the transformer 23.

Further, for example, in the power amplifier circuit 10A according to the present embodiment, the size of the power amplifier 13 (the peak amplifier) may be equal to or larger than the size of the power amplifier 12 (the carrier amplifier).

According to the above, the improvement in gain by suppressing the operation of the peak amplifier can be effectively realized, and the generation of noise accompanying an abrupt change in gain of the power amplifier circuit 10A can be effectively suppressed.

Further, for example, in the power amplifier circuit 10A according to the present embodiment, the size of the power amplifier 13 (the peak amplifier) may be larger than the size of the power amplifier 12 (the carrier amplifier).

According to the above, the improvement in gain by suppressing the operation of the peak amplifier can be effectively realized, and the generation of noise accompanying an abrupt change in gain of the power amplifier circuit 10A can be effectively suppressed.

### Embodiment 2

Next, Embodiment 2 will be described. The present embodiment is mainly different from the above-described Embodiment 1 in a fact that a comparator circuit is included in the power amplifier circuit instead of the current limit circuit. Hereinafter, the present embodiment will be described with reference to the drawings, focusing on the points that are different from Embodiment 1.

### [3.1 Circuit Configurations of Communication Device 6B, Radio Frequency Circuit 1B, and Power Amplifier Circuit 10B]

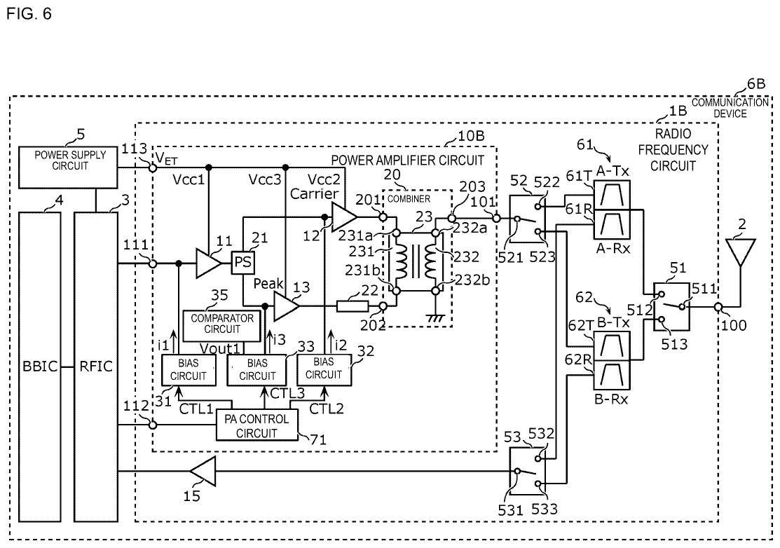

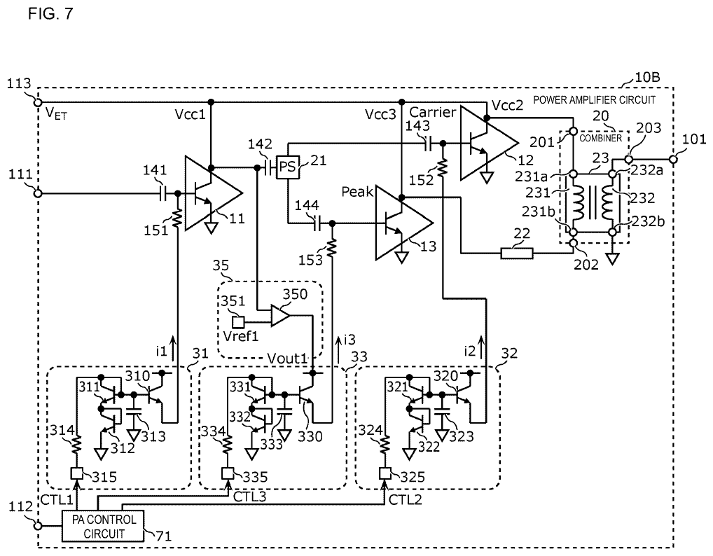

Circuit configurations of a communication device 6B, a radio frequency circuit 1B, and a power amplifier circuit 10B according to the present embodiment will be described with reference to FIGS. 6 and 7. FIG. 6 is a circuit configuration diagram of the power amplifier circuit 10B, the radio frequency circuit 1B, and the communication device 6B according to the present embodiment. FIG. 7 is a circuit configuration diagram of the power amplifier circuit 10B according to the present embodiment.

The communication device 6B according to the present embodiment is the same as the communication device 6A according to Embodiment 1, except that the present embodiment includes the radio frequency circuit 1B instead of the radio frequency circuit 1A, so a description thereof will be omitted. Further, the radio frequency circuit 1B according to the present embodiment is the same as the radio frequency circuit 1A according to Embodiment 1, except that the present embodiment includes the power amplifier circuit 10B instead of the power amplifier circuit 10A, so a description thereof will be omitted.

### [3.1.1 Circuit Configuration of Power Amplifier Circuit 10B]

The circuit configuration of the power amplifier circuit 10B will be described. As shown in FIGS. 6 and 7, the power amplifier circuit 10B is different from the power amplifier circuit 10A according to Embodiment 1 in a fact that the power amplifier circuit 10B includes a comparator circuit 35 instead of the current limit circuit 34. Therefore, the comparator circuit 35 will be described below.

The comparator circuit 35 is an example of a first comparator circuit and includes a comparator 350 and a reference voltage source 351. The reference voltage source 351 is connected to the comparator 350 and can apply a reference voltage Vref1 (a first reference voltage) to the comparator 350. Two input terminals of the comparator 350 are connected to the power supply terminal 113 and the reference voltage source 351, and an output terminal of the comparator 350 is connected to a collector terminal of the constant current amplifier transistor 330.

With this configuration, the comparator circuit 35 can switch the magnitude of a power supply voltage Vout1 (an example of a first power supply voltage) applied to the constant current amplifier transistor 330 of the bias circuit 33 according to the magnitude of the power supply voltage V_{ET}. Specifically, the comparator circuit 35 can switch the magnitude of the power supply voltage Vout1 applied to the constant current amplifier transistor 330 of the bias circuit 33 according to the comparison result of the power supply voltage V_{ET} and the reference voltage Vref1. For example, the comparator circuit 35 can apply the power supply voltage Vout1 having a predetermined magnitude to the constant current amplifier transistor 330 when the power supply voltage V_{ET} is higher than the reference voltage Vref1 and can apply the power supply voltage Vout1 having 0 volts to the constant current amplifier transistor 330 (that is, the power supply voltage is not applied) when the power supply voltage V_{ET} is lower than the reference voltage Vref1.

### [3.2 Relationship Between DC Bias Current and Power Supply Voltage]

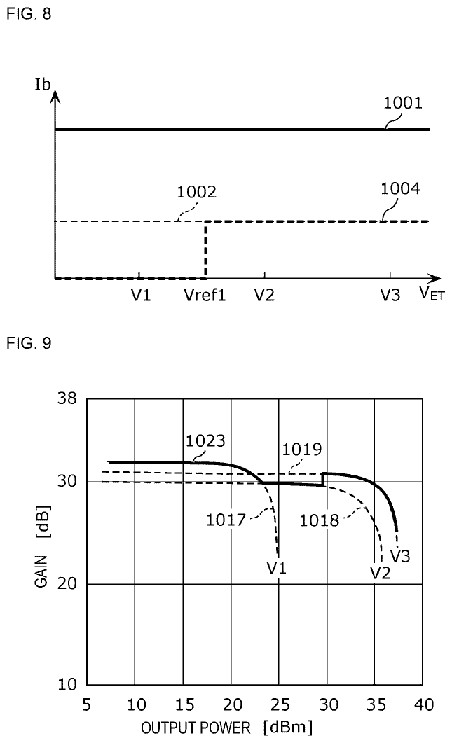

A relationship between the DC bias current Ib and the power supply voltage V_{ET}, which are respectively supplied to the power amplifiers 12 and 13 in such a power amplifier circuit 10B, will be described with reference to FIG. 8.

FIG. 8 is a graph showing a relationship between the DC bias current Ib and the power supply voltage V_{ET} in the present embodiment. In FIG. 8, the vertical axis indicates the DC bias current Ib, and the horizontal axis indicates the power supply voltage V_{ET}.

A line 1001 indicates a DC bias current supplied to the power amplifier 12 (the carrier amplifier). A line 1002 indicates a DC bias current supplied to the peak amplifier according to a comparative example. A line 1004 indicates a DC bias current supplied to the power amplifier 13 (the peak amplifier).

In the present embodiment, when the power supply voltage V_{ET} is lower than the reference voltage Vref1, the DC bias current is not supplied to the peak amplifier, and when the power supply voltage V_{ET} is higher than the reference voltage Vref1, the constant DC bias current, which does not depend on the power supply voltage V_{ET}, is supplied to the peak amplifier.

For example, in a case where V1<Vref1<V2<V3 is satisfied as in FIG. 8, when the power supply voltage V_{ET} having the voltage level V1 is applied to the peak amplifier, the DC bias current is not supplied to the peak amplifier. On the other hand, when the power supply voltage V_{ET} having the voltage levels V2 and V3 is applied to the peak amplifier, the constant DC bias current is supplied to the peak amplifier.

As described above, since the DC bias current is not supplied when the voltage level of the power supply voltage V_{ET} is low, the peak amplifier operation can be further suppressed when the input signal level is low, and it is possible to increase the load impedance that is seen from the carrier amplifier. As a result, the carrier amplifier can be operated with high efficiency, and the gain of the carrier amplifier can be increased.

### [3.3 Gain Change in Digital ET Mode]

Here, a relationship between the gain and output power of the power amplifier circuit 10B in the digital ET mode in which three discrete voltage levels V1 to V3 are selectively applied based on the envelope signal will be described with reference to FIG. 9.

FIG. 9 is a graph showing a relationship between the gain and the output power of the power amplifier circuit 10B according to the present embodiment. In FIG. 9, the vertical axis indicates a gain, and the horizontal axis indicates an output power.

Lines 1017 to 1019 represent the gain of the power amplifier circuit 10B according to the present embodiment when the voltage levels of the power supply voltage V_{ET} are respectively fixed to V1 to V3, and a line 1023 represents the gain of the power amplifier circuit 10B according to the present embodiment in the digital ET mode.

In the present embodiment, as apparent from the line 1023 in FIG. 9, the gain transitions smoothly at the switching between the voltage levels V1 and V2 of the power supply voltage V_{ET}. For example, even when the voltage level of the power supply voltage V_{ET} is switched from V1 to V2 at the output power of substantially 23 dBm, the gain transitions smoothly at substantially 30 dB.

In the present embodiment, similar to Embodiment 1, the size of the peak amplifier is preferably equal to or larger than the size of the carrier amplifier, and further preferably, the size of the peak amplifier is larger than the size of the carrier amplifier.

### [3.4 Effects and the Like]

As described above, the power amplifier circuit 10B according to the present embodiment includes the power amplifier 12 (the carrier amplifier), the power amplifier 13 (the peak amplifier), the external output terminal 101, the combiner 20 that includes the input terminal 201 connected to the output terminal of the power amplifier 12, the input terminal 202 connected to the output terminal of the power amplifier 13, and the output terminal 203 connected to the external output terminal 101, the bias circuit 32 that supplies the DC bias current i2 to the power amplifier 12, the bias circuit 33 that supplies the DC bias current i3 to the power amplifier 13, and a comparator circuit 35 that is connected to the bias circuit 33 and that switches the magnitude of the power supply voltage Vout1 applied to the bias circuit 33 according to the magnitude of the power supply voltage V_{ET} applied to the power amplifier circuit 10B.

According to the above, by switching the magnitude of the DC bias current i3 according to the magnitude of the power supply voltage V_{ET}, the operation of the power amplifier 13 can be controlled, and the load impedance, which is viewed from the power amplifier 12, can be controlled. That is, the gain of the power amplifier 12 can be controlled, and an abrupt change in gain of the power amplifier circuit 10B with respect to the change in power supply voltage V_{ET} can be suppressed. As a result, it is possible to suppress the generation of noise accompanying an abrupt change in gain of the power amplifier circuit 10B, and it is possible to suppress the deterioration of the characteristics of the power amplifier circuit 10B due to the tracking mode.

Further, for example, in the power amplifier circuit 10B according to the present embodiment, the combiner 20 may include the transformer 23 including the input side coil 231 of which both ends 231a and 231b are respectively connected to the input terminals 201 and 202, and the output side coil 232 of which both ends 232a and 232b are respectively connected to the output terminal 203 and the ground.

According to the above, the voltage of the radio frequency signal can be combined by using the transformer 23.

Further, for example, in the power amplifier circuit 10B according to the present embodiment, the size of the power amplifier 13 (the peak amplifier) may be equal to or larger than the size of the power amplifier 12 (the carrier amplifier).

According to the above, the improvement in gain by suppressing the operation of the peak amplifier can be effectively realized, and the generation of noise accompanying an abrupt change in gain of the power amplifier circuit 10B can be effectively suppressed.

Further, for example, in the power amplifier circuit 10B according to the present embodiment, the size of the power amplifier 13 (the peak amplifier) may be larger than the size of the power amplifier 12 (the carrier amplifier).

According to the above, the improvement in gain by suppressing the operation of the peak amplifier can be effectively realized, and the generation of noise accompanying an abrupt change in gain of the power amplifier circuit 10B can be effectively suppressed.

### Modification Example 1

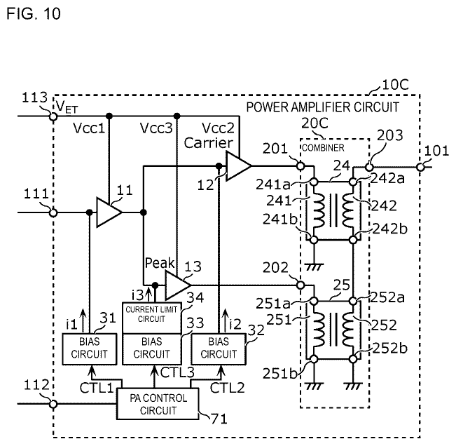

Next, Modification Example 1 will be described. The present modification example is a modification example of Embodiment 1 and is mainly different from Embodiment 1 in a fact that two transformers are included in the combiner. Hereinafter, the present modification example will be described with reference to FIG. 10, focusing on the difference from Embodiment 1.

### [4.1 Circuit Configuration of Power Amplifier Circuit 10C]

FIG. 10 is a circuit configuration diagram of a power amplifier circuit 10C according to the present modification example. The power amplifier circuit 10C is mainly different from the power amplifier circuit 10A according to Embodiment 1 in a fact that a combiner 20C is included instead of the combiner 20 included in the power amplifier circuit 10A, and the phase shifter 21 and the transmission line 22 included in the power amplifier circuit 10A are removed. Therefore, the combiner 20C will be described below.

The combiner 20C includes the input terminals 201 and 202 and an output terminal 203. The input terminal 201 is an example of a first input terminal and is connected to the output terminal of the power amplifier 12. The input terminal 202 is an example of a second input terminal and is connected to the output terminal of the power amplifier 13. The output terminal 203 is an example of a first output terminal and is connected to the external output terminal 101.

In the present modification example, the combiner 20C includes transformers 24 and 25. The transformer 24 is an example of a first transformer and includes an input side coil 241 and an output side coil 242. The input side coil 241 is an example of a first input side coil. Both ends 241a and 241b of the input side coil 241 are respectively connected to the input terminal 201 and the ground. Specifically, one end 241a of the input side coil 241 is connected to the output terminal of the power amplifier 12 with the input terminal 201 interposed therebetween, and the other end 241b of the input side coil 241 is connected to the ground. The output side coil 242 is an example of a first output side coil. Both ends 242a and 242b of the output side coil 242 are respectively connected to the output terminal 203 and the transformer 25. Specifically, one end 242a of the output side coil 242 is connected to the external output terminal 101 with the output terminal 203 interposed therebetween, and the other end 242b of the output side coil 242 is connected to the output side coil 252 of the transformer 25.

The transformer 25 is an example of a second transformer and includes an input side coil 251 and an output side coil 252. The input side coil 251 is an example of a second input side coil. Both ends 251a and 251b of the input side coil 251 are respectively connected to the input terminal 202 and the ground. Specifically, one end 251a of the input side coil 251 is connected to the output terminal of the power amplifier 13 with the input terminal 202 interposed therebetween, and the other end 251b of the input side coil 251 is connected to the ground. The output side coil 252 is an example of a second output side coil. Both ends 252a and 252b of the output side coil 252 are respectively connected to the transformer 24 and the ground. Specifically, one end 252a of the output side coil 252 is connected to the output side coil 242 of the transformer 24, and the other end 252b of the output side coil 252 is connected to the ground.

In the configuration, the combiner 20C can combine two input signals, which are from the input terminals 201 and 202, and output the input signals from the output terminal 203. Further, the combiner 20C can also output the input signal, which is from the input terminal 201, from the output terminal 203.

### [4.2 Effects and the Like]

As described above, in the power amplifier circuit 10C according to the present modification example, the combiner 20C may include the transformer 24 including the input side coil 241 and the output side coil 242, the transformer 25 including the input side coil 251 and the output side coil 252, both ends 241a and 241b of the input side coil 241 may be respectively connected to the input terminal 201 and the ground, both ends 242a and 242b of the output side coil 242 may be respectively connected to the output terminal 203 and the output side coil 252, both ends 251a and 251b of the input side coil 251 may be respectively connected to the input terminal 202 and the ground, and both ends 252a and 252b of the output side coil 252 may be respectively connected to the output side coil 242 and the ground.

According to the above, since the output terminals of the power amplifiers 12 and 13 are connected to transformers different from each other, it is not necessary to adjust a phase difference between two radio frequency signals, which are each amplified by the power amplifiers 12 and 13, to 180 degrees.

The present modification example can be applied to Embodiment 2 as well. In this case, by replacing the combiner 20 with the combiner 20C in the power amplifier circuit 10B and removing the phase shifter 21 and the transmission line 22 from the power amplifier circuit 10B, a power amplifier circuit according to Modification Example 1 of Embodiment 2 is realized.

### Modification Example 2

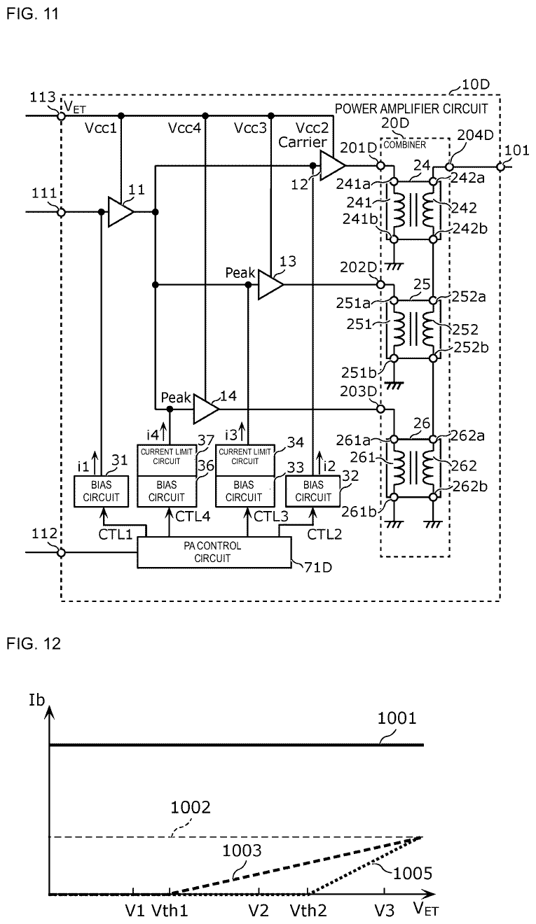

Next, Modification Example 2 will be described. The present modification example is a modification example of Embodiment 1 and is mainly different from the above-described Embodiment 1 in a fact that two peak amplifiers are included in the power amplifier circuit. Hereinafter, the present modification example will be described with reference to FIGS. 11 and 12, focusing on the difference from Embodiment 1.

### [5.1 Circuit Configuration of Power Amplifier Circuit 10D]

FIG. 11 is a circuit configuration diagram of a power amplifier circuit 10D according to the present modification example. The power amplifier circuit 10D includes power amplifiers 11 to 14, a combiner 20D, bias circuits 31 to 33 and 36, current limit circuits 34 and 37, a PA control circuit 71D, an external output terminal 101, an external input terminal 111, a control terminal 112, and a power supply terminal 113.

The power amplifier 14 is an example of a second peak amplifier and is connected between the external input terminal 111 and the external output terminal 101. Specifically, an input terminal of the power amplifier 14 is connected to an output terminal of the power amplifier 11. The output terminal of the power amplifier 14 is connected to the input terminal 203D of the combiner 20D. In the present embodiment, although the power amplifier 14 includes a bipolar transistor as an amplifier transistor, the power amplifier 14 may include a MOSFET instead of the bipolar transistor.

The combiner 20D includes input terminals 201D to 203D and an output terminal 204D. The input terminal 201D is an example of a first input terminal and is connected to the output terminal of the power amplifier 12. The input terminal 202D is an example of a second input terminal and is connected to the output terminal of the power amplifier 13. The input terminal 203D is an example of a third input terminal and is connected to the output terminal of the power amplifier 14. The output terminal 204D is an example of a first output terminal and is connected to the external output terminal 101.

In the present modification example, the combiner 20D includes transformers 24 to 26.

The transformer 24 is an example of a first transformer and includes an input side coil 241 and an output side coil 242. The input side coil 241 is an example of a first input side coil. Both ends 241a and 241b of the input side coil 241 are respectively connected to the input terminal 201D and the ground. Specifically, one end 241a of the input side coil 241 is connected to the output terminal of the power amplifier 12 with the input terminal 201D interposed therebetween, and the other end 241b of the input side coil 241 is connected to the ground. The output side coil 242 is an example of a first output side coil. Both ends 242a and 242b of the output side coil 242 are respectively connected to the output terminal 204D and the transformer 25. Specifically, one end 242a of the output side coil 242 is connected to the external output terminal 101 with the output terminal 204D interposed therebetween, and the other end 242b of the output side coil 242 is connected to the output side coil 252 of the transformer 25.

The transformer 25 is an example of a second transformer and includes an input side coil 251 and an output side coil 252. The input side coil 251 is an example of a second input side coil. Both ends 251a and 251b of the input side coil 251 are respectively connected to the input terminal 202D and the ground. Specifically, one end 251a of the input side coil 251 is connected to the output terminal of the power amplifier 13 with the input terminal 202D interposed therebetween, and the other end 251b of the input side coil 251 is connected to the ground. The output side coil 252 is an example of a second output side coil. Both ends 252a and 252b of the output side coil 252 are respectively connected to the transformers 24 and 26. Specifically, one end 252a of the output side coil 252 is connected to the output side coil 242 of the transformer 24, and the other end 252b of the output side coil 252 is connected to the output side coil 262 of the transformer 26.

The transformer 26 is an example of a third transformer and includes an input side coil 261 and an output side coil 262. The input side coil 261 is an example of a third input side coil. Both ends 261a and 261b of the input side coil 261 are respectively connected to the input terminal 203D and the ground. Specifically, one end 261a of the input side coil 261 is connected to the output terminal of the power amplifier 14 with the input terminal 203D interposed therebetween, and the other end 261b of the input side coil 261 is connected to the ground. The output side coil 262 is an example of a third output side coil. Both ends 262a and 262b of the output side coil 262 are respectively connected to the transformer 25 and the ground. Specifically, one end 262a of the output side coil 262 is connected to the output side coil 252 of the transformer 25, and the other end 262b of the output side coil 262 is connected to the ground.

In the configuration, the combiner 20D can combine three input signals, which are from the input terminals 201D to 203D, and output the input signals from the output terminal 204D. Further, the combiner 20D can also combine two input signals, which are from the input terminals 201D and 202D, and output the input signals from the output terminal 204D. Further, the combiner 20D can also output the input signal, which is from the input terminal 201D, from the output terminal 204D.

The bias circuit 36 is an example of a third bias circuit and has the same circuit configuration as the bias circuits 31 and 32. The bias circuit 36 can output a DC bias current i4 (an example of a third DC bias current) toward a base terminal of the power amplifier 14.

A current limit circuit 37 is an example of a second modulation circuit and has the same circuit configuration as the current limit circuit 34. The current limit circuit 37 can change (modulate) a magnitude of the DC bias current i4 according to the magnitude of the power supply voltage V_{ET}.

The PA control circuit 71D controls the bias circuits 31 to 33 and 36. Specifically, the PA control circuit 71D respectively outputs control signals CTL1 to CTL4 to the bias circuits 31 to 33 and 36 based on the control signal from the RFIC 3. The PA control circuit 71D may control other circuit components (for example, the switches 51 to 53). Further, the PA control circuit 71D is not necessarily included in the power amplifier circuit 10D.

### [5.2 Relationship Between DC Bias Current and Power Supply Voltage]

A relationship between the DC bias current Ib and the power supply voltage V_{ET}, which are respectively supplied to the power amplifiers 12 and 14 in such a power amplifier circuit 10D, will be described with reference to FIG. 12.

FIG. 12 is a graph showing a relationship between the DC bias current Ib and the power supply voltage V_{ET} in the present modification example. In FIG. 12, the vertical axis indicates the DC bias current Ib, and the horizontal axis indicates the power supply voltage V_{ET}.

A line 1001 indicates a DC bias current supplied to the power amplifier 12 (the carrier amplifier). A line 1002 indicates a DC bias current supplied to the peak amplifier according to a comparative example. A line 1003 indicates a DC bias current supplied to the power amplifier 13 (the first peak amplifier). A line 1005 indicates a DC bias current supplied to the power amplifier 14 (the second peak amplifier).

In the present modification example, when the power supply voltage V_{ET} is lower than the standard voltage Vth1, the DC bias current is not supplied to the first peak amplifier, and when the power supply voltage V_{ET} is higher than the standard voltage Vth1, the DC bias current, which is supplied to the first peak amplifier, is increased as the power supply voltage V_{ET} is increased. Further, when the power supply voltage V_{ET} is lower than the standard voltage Vth2 (an example of a second standard voltage), the DC bias current is not supplied to the second peak amplifier, and when the power supply voltage V_{ET} is higher than the standard voltage Vth2, the DC bias current, which is supplied to the second peak amplifier, is increased as the power supply voltage V_{ET} is increased.

For example, in a case where V1<Vth1<V2<Vth2<V3 is satisfied as in FIG. 12, when the power supply voltage V_{ET} having the voltage level V1 is applied to the first peak amplifier and the second peak amplifier, the DC bias current is not supplied to the first peak amplifier and the second peak amplifier. Further, when the power supply voltage V_{ET} having the voltage level V2 is applied to the first peak amplifier and the second peak amplifier, the DC bias current is supplied to the first peak amplifier, and the DC bias current is not supplied to the second peak amplifier. Further, when the power supply voltage V_{ET} having the voltage level V3 is applied to the first peak amplifier and the second peak amplifier, the DC bias current is supplied to the first peak amplifier and the second peak amplifier.

Therefore, in addition to suppressing an abrupt change in gain when the voltage level of the power supply voltage V_{ET} is switched from V1 to V2, it is also possible to suppress an abrupt change in gain when the voltage level of power supply voltage V_{ET} is switched from V2 to V3.

### [5.3 Effects and the Like]

As described above, the power amplifier circuit 10D according to the present modification example may further include the power amplifier 14 (the second peak amplifier), the bias circuit 36 that supplies the DC bias current i4 to the power amplifier 14, and the current limit circuit 37 that is connected between the power amplifier 14 and the bias circuit 36 and that changes the magnitude of the DC bias current i4 according to the magnitude of the power supply voltage V_{ET}, the combiner 20D may further include the input terminal 203D that is connected to the power amplifier 14, the transformer 24 that includes the input side coil 241 and the output side coil 242, the transformer 25 that includes the input side coil 251 and the output side coil 252, and the transformer 26 that includes the input side coil 261 and the output side coil 262, both ends 241a and 241b of the input side coil 241 may be respectively connected to the input terminal 201D and the ground, both ends 242a and 242b of the output side coil 242 may be respectively connected to the output terminal 204D and the output side coil 252, both ends 251a and 251b of the input side coil 251 may be respectively connected to the input terminal 202D and the ground, and both ends 252a and 252b of the output side coil 252 may be respectively connected to the output side coil 242 and the ground.

According to the above, since the power amplifier circuit 10D includes two peak amplifiers (the power amplifiers 13 and 14), the amplification efficiency can be further improved.

Further, for example, in the power amplifier circuit 10D according to the present modification example, the current limit circuit 34 may increase the DC bias current i3 as the power supply voltage V_{ET} is increased when the power supply voltage V_{ET} is higher than the standard voltage Vth1, and the current limit circuit 37 may increase the DC bias current i4 as the power supply voltage V_{ET} is increased when the power supply voltage V_{ET} is higher than the standard voltage Vth2 different from the standard voltage Vth1.

According to the above, the standard voltages Vth1 and Vth2, which are different from each other, can be used in the two current limit circuits 34 and 37. Therefore, even when three or more discrete voltage levels are used in the power supply voltage V_{ET}, an abrupt change in gain with respect to the switching of the voltage level can be effectively suppressed.

### Modification Example 3

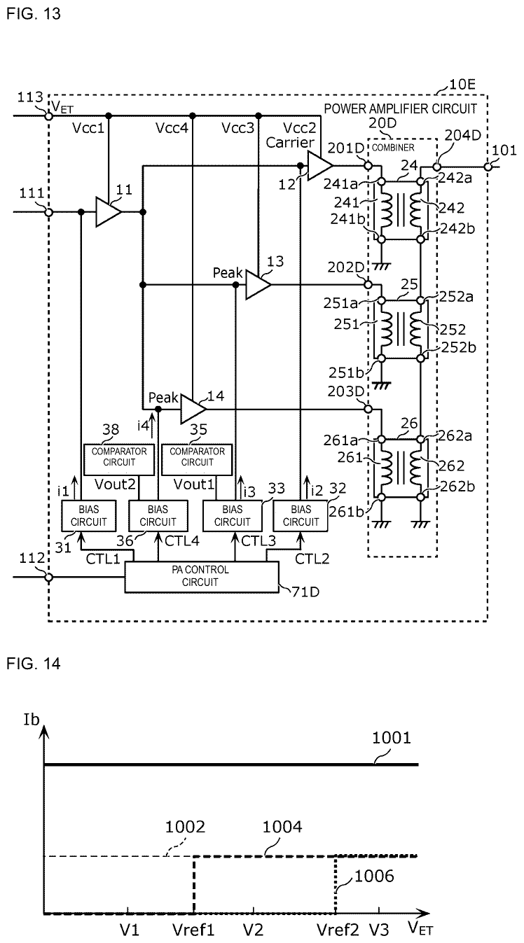

Next, Modification Example 3 will be described. The present modification example is a modification example of Embodiment 2 and is similar to Modification Example 2. Specifically, the present modification example mainly differs from Embodiment 2 in a fact that the power amplifier circuit includes two peak amplifiers and mainly differs from Modification Example 2 in a fact that comparator circuits 35 and 38 are included instead of the current limit circuits 34 and 37. Hereinafter, the present modification example will be described with reference to FIGS. 13 and 14, focusing on the differences from Embodiment 2 and Modification Example 2.

### [6.1 Circuit Configuration of Power Amplifier Circuit 10E]

FIG. 13 is a circuit configuration diagram of a power amplifier circuit 10E according to the present modification example. The power amplifier circuit 10E includes power amplifiers 11 to 14, a combiner 20D, bias circuits 31 to 33 and 36, comparator circuits 35 and 38, a PA control circuit 71D, an external output terminal 101, an external input terminal 111, a control terminal 112, and a power supply terminal 113.

The comparator circuit 38 is an example of a second comparator circuit and has the same circuit configuration as the comparator circuit 35. The comparator circuit 38 can switch the magnitude of a power supply voltage Vout2 (an example of a second power supply voltage) applied to the bias circuit 36 according to the magnitude of the power supply voltage V_{ET}. Specifically, the comparator circuit 38 can switch the magnitude of the power supply voltage Vout2 (an example of a second reference voltage) applied to the bias circuit 36 according to the comparison result of the power supply voltage V_{ET} and a reference voltage Vref2. For example, the comparator circuit 38 can apply the power supply voltage Vout2 having a predetermined magnitude to the bias circuit 36 when the power supply voltage V_{ET} is higher than the reference voltage Vref2 and can apply the power supply voltage Vout2 having 0 volts to the bias circuit 36 (that is, the power supply voltage is not applied) when the power supply voltage V_{ET} is lower than the reference voltage Vref2.

### [6.2 Relationship Between DC Bias Current and Power Supply Voltage]

A relationship between the DC bias current Ib and the power supply voltage V_{ET}, which are respectively supplied to the power amplifiers 12 and 14 in such a power amplifier circuit 10E, will be described with reference to FIG. 14.

FIG. 14 is a graph showing a relationship between the DC bias current Ib and the power supply voltage V_{ET} in the present modification example. In FIG. 14, the vertical axis indicates the DC bias current Ib, and the horizontal axis indicates the power supply voltage V_{ET}.

A line 1001 indicates a DC bias current supplied to the power amplifier 12 (the carrier amplifier). A line 1002 indicates a DC bias current supplied to the peak amplifier according to a comparative example. A line 1004 indicates a DC bias current supplied to the power amplifier 13 (the first peak amplifier). A line 1006 indicates a DC bias current supplied to the power amplifier 14 (the second peak amplifier).

In the present modification example, when the power supply voltage V_{ET} is lower than the reference voltage Vref1, the DC bias current is not supplied to the first peak amplifier, and when the power supply voltage V_{ET} is higher than the reference voltage Vref1, the constant DC bias current, which does not depend on the power supply voltage V_{ET}, is supplied to the first peak amplifier. Further, when the power supply voltage V_{ET} is lower than the standard voltage Vth2, the DC bias current is not supplied to the second peak amplifier, and when the power supply voltage V_{ET} is higher than the standard voltage Vth2, the constant DC bias current, which does not depend on the power supply voltage V_{ET}, is supplied to the second peak amplifier.

For example, in a case where V1<Vref1<V2<Vref2<V3 is satisfied as in FIG. 14, when the power supply voltage V_{ET} having the voltage level V1 is applied to the first peak amplifier and the second peak amplifier, the DC bias current is not supplied to the first peak amplifier and the second peak amplifier. Further, when the power supply voltage V_{ET} having the voltage level V2 is applied to the first peak amplifier and the second peak amplifier, the constant DC bias current is supplied to the first peak amplifier, and the DC bias current is not supplied to the second peak amplifier. Further, when the power supply voltage V_{ET} having the voltage level V3 is applied to the first peak amplifier and the second peak amplifier, the constant DC bias current is supplied to the first peak amplifier and the second peak amplifier.

Therefore, in addition to suppressing an abrupt change in gain when the voltage level of the power supply voltage V_{ET} is switched from V1 to V2, it is also possible to suppress an abrupt change in gain when the voltage level of power supply voltage V_{ET} is switched from V2 to V3.

### [6.3 Effects and the Like]

As described above, the power amplifier circuit 10E according to the present modification example may further include the power amplifier 14 (the second peak amplifier), the bias circuit 36 that supplies the DC bias current i4 to the power amplifier 14, and the comparator circuit 38 that is connected to the bias circuit 36 and that switches the magnitude of the power supply voltage Vout2 applied to the bias circuit 36 according to the magnitude of the power supply voltage V_{ET} applied to the power amplifier circuit 10E, the combiner 20D may further include the input terminal 203D that is connected to the power amplifier 14, the transformer 24 that includes the input side coil 241 and the output side coil 242, the transformer 25 that includes the input side coil 251 and the output side coil 252, and the transformer 26 that includes the input side coil 261 and the output side coil 262, both ends 241a and 241b of the input side coil 241 may be respectively connected to the input terminal 201D and the ground, both ends 242a and 242b of the output side coil 242 may be respectively connected to the output terminal 204D and the output side coil 252, both ends 251a and 251b of the input side coil 251 may be respectively connected to the input terminal 202D and the ground, and both ends 252a and 252b of the output side coil 252 may be respectively connected to the output side coil 242 and the ground.

According to the above, since the power amplifier circuit 10E includes two peak amplifiers (the power amplifiers 13 and 14), the amplification efficiency can be further improved.

Further, for example, in the power amplifier circuit 10E according to the present modification example, the comparator circuit 35 does not necessarily apply the power supply voltage Vout1 to the bias circuit 33 when the power supply voltage V_{ET} is lower than the reference voltage Vref1 and may apply the power supply voltage Vout1 to the bias circuit 33 when the power supply voltage V_{ET} is higher than the reference voltage Vref1. The comparator circuit 38 does not necessarily apply the power supply voltage Vout2 to the bias circuit 36 when the power supply voltage V_{ET} is lower than the reference voltage Vref2 different from the reference voltage Vref1 and may apply the power supply voltage Vout2 to the bias circuit 36 when the power supply voltage V_{ET} is higher than the reference voltage Vref2.

According to the above, the reference voltages Vref1 and Vref2, which are different from each other, can be used in the two comparator circuits 35 and 38. Therefore, even when three or more discrete voltage levels are used in the power supply voltage V_{ET}, an abrupt change in gain with respect to the switching of the voltage level can be effectively suppressed.

### Modification Example 4

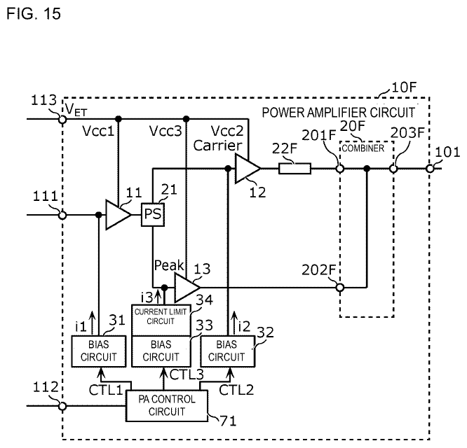

Next, Modification Example 4 of Embodiment 1 will be described. The present modification example is mainly different from the above-described Embodiment 1 in a fact that the transformer is not included in the combiner. Hereinafter, the present modification example will be described with reference to FIG. 15, focusing on the difference from Embodiment 1.

### [7.1 Circuit Configuration of Power Amplifier Circuit 10F]

FIG. 15 is a circuit configuration diagram of a power amplifier circuit 10F according to the present modification example. The power amplifier circuit 10F is mainly different from the power amplifier circuit 10A according to Embodiment 1 in a fact that a combiner 20F and a transmission line 22F are included instead of the combiner 20 and the transmission line 22 included in the power amplifier circuit 10A. Therefore, the combiner 20F and the transmission line 22F will be described below.

The combiner 20F includes input terminals 201F and 202F and an output terminal 203F. The input terminal 201F is an example of a first input terminal and is connected to the output terminal of the power amplifier 12 with the transmission line 22F interposed therebetween. The input terminal 202F is an example of a second input terminal and is connected to the output terminal of the power amplifier 13. The output terminal 203F is an example of a first output terminal and is connected to the external output terminal 101. In the present modification example, the combiner 20F is a current combiner and does not include a transformer.

The transmission line 22F is, for example, a ¼ wavelength transmission line and can rotate a load impedance by 180 degrees on the Smith chart. The transmission line 22F may be referred to as a phase adjuster or a phase shifter. A length of the transmission line 22F is determined based on the bands A and B. The transmission line 22F is connected between the output terminal of the power amplifier 12 and the input terminal 201F of the combiner 20F. In the connection configuration, the transmission line 22F can shift the phase of the transmission signal in the bands A and B, which are amplified by the power amplifier 12, by −90 degrees (delay by 90 degrees). The transmission line 22F may include at least one of an inductor and a capacitor. Accordingly, the reduction in length of the transmission line 22F can be achieved.

### [7.2 Effects and the Like]

As described above, in the power amplifier circuit 10F according to the present modification example, the combiner 20F does not necessarily include a transformer.

According to the above, the current of the radio frequency signal can be combined.

The present modification example can be applied to Embodiment 2 as well. In this case, by respectively replacing the combiner 20 and the transmission line 22 with the combiner 20F and the transmission line 22F in the power amplifier circuit 10B, a power amplifier circuit according to Modification Example 4 of Embodiment 2 is realized.

### Other Embodiments

Although the power amplifier circuit according to the present disclosure has been described above based on the embodiments and the modification examples thereof, the power amplifier circuit according to the present disclosure is not limited to the above-described embodiments and modification examples thereof. Other embodiments, which are realized by combining any configuration elements in the above embodiments and modification examples thereof, modification examples, which can be obtained by making various modifications with respect to the above-described embodiments and the modification examples thereof that can be thought of by those skilled in the art without departing from the gist of the present disclosure, or various devices incorporating the power amplifier circuit are also included in the present disclosure.

For example, in the circuit configuration of the power amplifier circuit according to each of the above embodiments and each of the modification examples, other circuit elements, wiring, or the like may be inserted between the paths connecting each circuit element and signal path disclosed in the drawings. For example, an impedance matching circuit may be inserted between the power amplifier 12 and the combiner 20 and/or between the power amplifier 13 and the combiner 20. The impedance matching circuit can be configured with, for example, an inductor and/or a capacitor.

In each of the above embodiments and each of the modification examples, although the power amplifier circuit includes one or two peak amplifiers, the number of peak amplifiers is not limited thereto. For example, the power amplifier circuit may include three or more peak amplifiers. In this case, the power amplifier circuit may include the current limit circuit or the comparator circuit for each of the three or more peak amplifiers and may include the current limit circuit or the comparator circuit only for some of the three or more peak amplifiers.

In each of the above embodiments and each of the modification examples, although the digital ET mode is used as the tracking mode, the present disclosure is not limited thereto. That is, in each of the above embodiments and each of the modification examples, the deterioration of the characteristics of the power amplifier circuit can be suppressed even when other tracking mode (for example, the APT mode or the analog ET mode) is used.

### INDUSTRIAL APPLICABILITY

The present disclosure can be widely used in communication devices such as mobile phones as a power amplifier circuit disposed in a multi-band front end portion.

### REFERENCE SIGNS LIST

1A, 1B radio frequency circuit
2 antenna
3 RFIC
4 BBIC
5 power supply circuit
6A, 6B communication device
10A, 10B, 10C, 10D, 10E, 10F power amplifier circuit
11, 12, 13, 14 power amplifier
15 low-noise amplifier
20, 20C, 20D, 20F combiner
21 phase shifter
22, 22F transmission line
23, 24, 25, 26 transformer
31, 32, 33, 36 bias circuit
34, 37 current limit circuit
35, 38 comparator circuit
51, 52, 53 switch
61, 62 duplexer
61R, 62R reception filter
61T, 62T transmission filter
71, 71D PA control circuit
100 antenna connection terminal
101 external output terminal
111 external input terminal
112 control terminal
113 power supply terminal
201, 201D, 201F, 202, 202D, 202F, 203D input terminal
203, 203F, 204D output terminal
231, 241, 251, 261 input side coil
232, 242, 252, 262 output side coil

1. A power amplifier circuit comprising:
a carrier amplifier;
a first peak amplifier;
an external output terminal;
a combiner that includes a first input terminal connected to an output terminal of the carrier amplifier, a second input terminal connected to an output terminal of the first peak amplifier, and a first output terminal connected to the external output terminal;
a first bias circuit configured to supply a first DC bias current to the carrier amplifier;
a second bias circuit configured to supply a second DC bias current to the first peak amplifier; and
a first modulation circuit that is connected between the first peak amplifier and the second bias circuit, and configured to change a magnitude of the second DC bias current according to a magnitude of a power supply voltage applied to the power amplifier circuit.

2. The power amplifier circuit of claim 1, wherein
the combiner includes a transformer including an input side coil of which both ends are respectively connected to the first input terminal and the second input terminal and an output side coil of which both ends are respectively connected to the first output terminal and a ground.

3. The power amplifier circuit of claim 1, wherein the combiner includes:
a first transformer including a first input side coil and a first output side coil, and
a second transformer including a second input side coil and a second output side coil.

4. The power amplifier circuit of claim 3, wherein
both ends of the first input side coil are respectively connected to the first input terminal and a ground,
both ends of the first output side coil are respectively connected to the first output terminal and the second output side coil,
both ends of the second input side coil are respectively connected to the second input terminal and a ground, and
both ends of the second output side coil are respectively connected to the first output side coil and a ground.

5. The power amplifier circuit of claim 1, wherein
a size of the first peak amplifier is equal to or greater than a size of the carrier amplifier.

6. The power amplifier circuit of claim 5, wherein
the size of the first peak amplifier is greater than the size of the carrier amplifier.

7. The power amplifier circuit of claim 1, further comprising:
a second peak amplifier;
a third bias circuit configured to supply a third DC bias current to the second peak amplifier; and
a second modulation circuit that is connected between the second peak amplifier and the third bias circuit and configured to change a magnitude of the third DC bias current according to the magnitude of the power supply voltage.

8. The power amplifier circuit of claim 7, wherein the combiner further includes:
a third input terminal connected to the second peak amplifier,
a first transformer including a first input side coil and a first output side coil,
a second transformer including a second input side coil and a second output side coil, and
a third transformer including a third input side coil and a third output side coil.

9. The power amplifier circuit of claim 8, wherein
both ends of the first input side coil are respectively connected to the first input terminal and a ground,
both ends of the first output side coil are respectively connected to the first output terminal and the second output side coil,
both ends of the second input side coil are respectively connected to the second input terminal and a ground, and
both ends of the second output side coil are respectively connected to the first output side coil and a ground.

10. The power amplifier circuit of claim 7, wherein
the first modulation circuit is configured to increase the second DC bias current as the power supply voltage is increased in a case that the power supply voltage is higher than a first standard voltage, and
the second modulation circuit is configured to increase the third DC bias current as the power supply voltage is increased in a case that the power supply voltage is higher than a second standard voltage different from the first standard voltage.

11. A power amplifier circuit comprising:
a carrier amplifier;
a first peak amplifier;
an external output terminal;
a combiner that includes a first input terminal connected to an output terminal of the carrier amplifier, a second input terminal connected to an output terminal of the first peak amplifier, and a first output terminal connected to the external output terminal;
a first bias circuit configured to supply a first DC bias current to the carrier amplifier;
a second bias circuit configured to supply a second DC bias current to the first peak amplifier; and
a first comparator circuit that is connected to the second bias circuit and configured to switch a magnitude of a first power supply voltage applied to the second bias circuit according to a magnitude of a power supply voltage applied to the power amplifier circuit.

12. The power amplifier circuit of claim 11, wherein
the combiner includes a transformer including an input side coil of which both ends are respectively connected to the first input terminal and the second input terminal and an output side coil of which both ends are respectively connected to the first output terminal and a ground.

13. The power amplifier circuit of claim 11, wherein the combiner includes:
a first transformer including a first input side coil and a first output side coil, and
a second transformer including a second input side coil and a second output side coil.

14. The power amplifier circuit of claim 13, wherein
both ends of the first input side coil are respectively connected to the first input terminal and a ground,
both ends of the first output side coil are respectively connected to the first output terminal and the second output side coil,
both ends of the second input side coil are respectively connected to the second input terminal and a ground, and
both ends of the second output side coil are respectively connected to the first output side coil and a ground.

15. The power amplifier circuit of claim 11, wherein
a size of the first peak amplifier is equal to or greater than a size of the carrier amplifier.

16. The power amplifier circuit according to claim 15, wherein
the size of the first peak amplifier is greater than the size of the carrier amplifier.

17. The power amplifier circuit of claim 11, further comprising:
a second peak amplifier;
a third bias circuit configured to supply a third DC bias current to the second peak amplifier; and
a second comparator circuit that is connected to the third bias circuit and configured to switch a magnitude of a second power supply voltage applied to the third bias circuit according to the magnitude of the power supply voltage applied to the power amplifier circuit.

18. The power amplifier circuitry of claim 17, wherein the combiner further includes:
a third input terminal connected to the second peak amplifier;
a first transformer including a first input side coil and a first output side coil;
a second transformer including a second input side coil and a second output side coil; and
a third transformer including a third input side coil and a third output side coil, wherein
both ends of the first input side coil are respectively connected to the first input terminal and a ground,
both ends of the first output side coil are respectively connected to the first output terminal and the second output side coil,
both ends of the second input side coil are respectively connected to the second input terminal and a ground, and
both ends of the second output side coil are respectively connected to the first output side coil and a ground.

19. The power amplifier circuit of claim 17, wherein
the first comparator circuit is configured to not apply the first power supply voltage to the second bias circuit in a case that the power supply voltage applied to the power amplifier circuit is lower than a first reference voltage and apply the first power supply voltage to the second bias circuit in a case that the power supply voltage applied to the power amplifier circuit is higher than the first reference voltage, and
the second comparator circuit is configured to not apply the second power supply voltage to the third bias circuit in a case that the power supply voltage applied to the power amplifier circuit is lower than a second reference voltage different from the first reference voltage and apply the second power supply voltage to the third bias circuit in a case that the power supply voltage applied to the power amplifier circuit is higher than the second reference voltage.

20. A power amplifier circuit comprising:
a carrier amplifier;
a peak amplifier;
an external output terminal;
a transformer that includes an input side coil of which both ends are respectively connected to an output terminal of the carrier amplifier and an output terminal of the peak amplifier and an output side coil of which both ends are respectively connected to the external output terminal and a ground;
a first bias circuit configured to supply a first DC bias current to the carrier amplifier;
a second bias circuit configured to supply a second DC bias current to the peak amplifier; and
a modulation circuit that is connected between the peak amplifier and the second bias circuit and configured to change a magnitude of the second DC bias current according to a magnitude of a power supply voltage applied to the power amplifier circuit.
